(19) United States
(12) Patent Application Publication
(10) Pub. No.: US 2022/0399235 A1
(43) Pub. Date: Dec. 15, 2022

(54) MANUFACTURING METHOD FOR DEVICE CHIP

(71) Applicant: DISCO CORPORATION, Tokyo (JP)

(72) Inventors: Katsuhiko SUZUKI, Tokyo (JP); Hayato KIUCHI, Tokyo (JP); Kentaro ODANAKA, Tokyo (JP); Nobuyasu KITAHARA, Tokyo (JP); Daigo SHITABO, Tokyo (JP)

(21) Appl. No.: 17/806,832

(22) Filed: Jun. 14, 2022

(30) Foreign Application Priority Data
Jun. 15, 2021 (JP) 2021-099660

(51) Int. Cl. H01L 21/78; H01L 21/67; H01L 21/683; B23K 26/18; H01L 21/268

(52) U.S. Cl. CPC H01L 21/78; H01L 21/67092; H01L 21/6838; B23K 26/18; H01L 21/268

(57) ABSTRACT

A manufacturing method for a device chip includes a wafer preparation step of preparing a wafer including a base substrate, a laser beam absorbing layer layered on a front surface of the base substrate, and a device layer being layered on the laser beam absorbing layer and having devices formed in respective separate regions demarcated by a plurality of crossing division lines, a device layer dividing step of forming respective division grooves that divide at least the device layer into individual device chips along the plurality of division lines, and a lift-off step of, after the device layer dividing step is carried out, applying a laser beam of such a wavelength as to be absorbed in the laser beam absorbing layer, from the base substrate side, and lifting off a device chip from the front surface of the base substrate.

### BACKGROUND OF THE INVENTION

### Field of the Invention

The present invention relates to a manufacturing method for a device chip.

### Description of the Related Art

Along with reduction in thickness of electronic equipment, a device chip is also demanded to be thinned to 100 μm or less. To meet the demand for reducing the thickness of the device chip, there has widely been adopted a technique of thinning only a region corresponding to devices of a wafer while making the thickness of an outer peripheral region remain as it is, to prevent breakage of the wafer at a time of handling the wafer (for example, see Japanese Patent Laid-Open No. 2021-5621), for example.

### SUMMARY OF THE INVENTION

Meanwhile, one type of wafer is a silicon on insulator wafer (what is generally called an SOI wafer). The SOI wafer includes an insulating layer called a buried oxide (BOX) layer made of SiO₂ formed on a base substrate made of silicon or the like, and has a device layer including a rewiring layer constituting devices that is formed on the insulating layer.

In recent years, there has been a demand for achieving further reduction in thickness of a device chip by fully removing the base substrate made of silicon or the like included in such an SOI wafer described above, to obtain a device chip including only the device layer.

It is accordingly an object of the present invention to provide a manufacturing method for a device chip by which a novel process of manufacturing a device chip including only a device layer can be achieved.

In accordance with an aspect of the present invention, there is provided a manufacturing method for a device chip, including a wafer preparation step of preparing a wafer including a base substrate, a laser beam absorbing layer layered on a front surface of the base substrate, and a device layer being layered on the laser beam absorbing layer and having devices formed in respective separate regions demarcated by a plurality of crossing division lines, a device layer dividing step of forming respective division grooves that divide at least the device layer into individual device chips along the plurality of division lines, and a lift-off step of, after the device layer dividing step is carried out, applying a laser beam of such a wavelength as to be absorbed in the laser beam absorbing layer, from the base substrate side, and lifting off a device chip from the front surface of the base substrate.

Preferably, the manufacturing method for a device chip may further include a transfer member arranging step of arranging a transfer member to a front surface of the device layer, before the lift-off step is carried out.

According to the present invention, an advantageous effect of achieving a novel process of manufacturing a device chip including only a device layer is produced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a wafer to be processed in a manufacturing method for a device chip according to a preferred embodiment of the present invention;

FIG. 2 is a sectional view of the wafer depicted in FIG. 1;

FIG. 3 is a flow chart of the manufacturing method for a device chip according to the embodiment of the present invention;

FIG. 4 is a perspective view schematically illustrating a device layer dividing step of the manufacturing method for a device chip depicted in FIG. 3;

FIG. 5 is a schematic sectional view of the wafer that has undergone the device layer dividing step of the manufacturing method for a device chip depicted in FIG. 3;

FIG. 6 is a schematic sectional view of the wafer that has undergone a transfer member arranging step of the manufacturing method for a device chip depicted in FIG. 3;

FIG. 7 is a sectional view schematically illustrating a state in which a laser beam is applied to the wafer in a lift-off step of the manufacturing method for a device chip depicted in FIG. 3;

FIG. 8 is a plan view illustrating a trajectory of a focusing point of the laser beam in the lift-off step of the manufacturing method for a device chip depicted in FIG. 3; and

FIG. 9 is a sectional view schematically illustrating a state in which a base substrate is removed in the lift-off step of the manufacturing method for a device chip depicted in FIG. 3.

### DETAILED DESCRIPTION OF THE PREFERRED EMBODIMENT

A preferred embodiment of the present invention will now be described in detail with reference to the drawings. The present invention is not limited to this preferred embodiment. Further, the components used in this preferred embodiment may include those that can easily be assumed by persons skilled in the art or substantially the same elements as those known in the art. Further, the configurations described below may suitably be combined. Further, the configurations may variously be omitted, replaced, or changed without departing from the scope of the present invention.

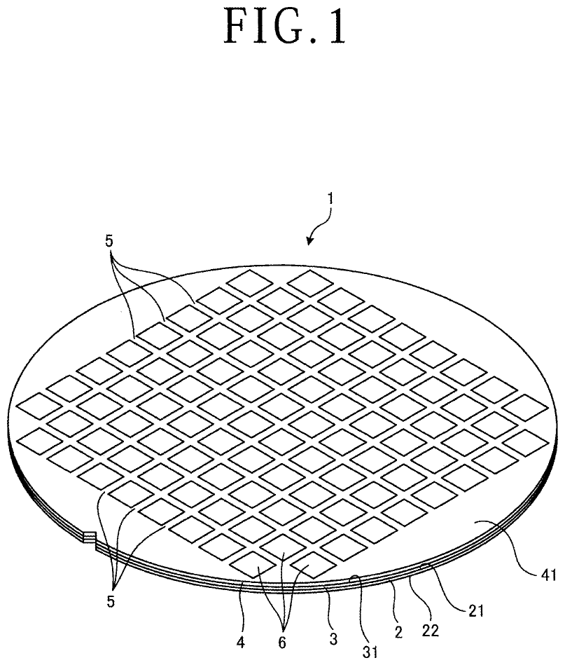

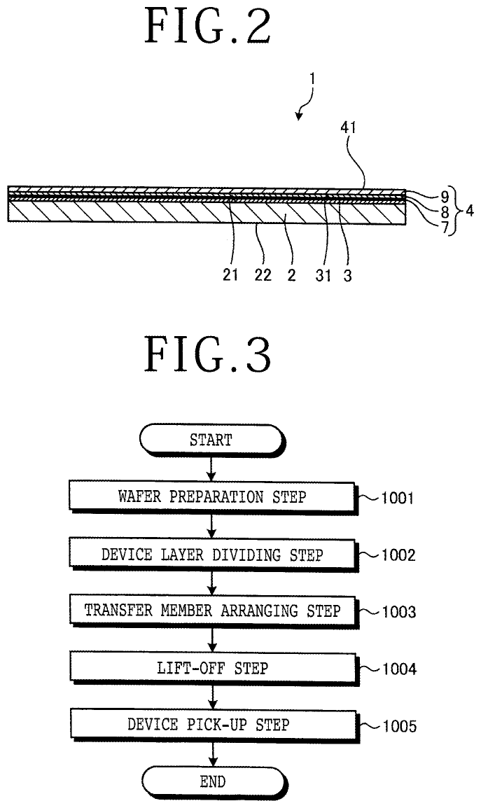

A manufacturing method for a device chip according to the embodiment of the present invention will be described with reference to the drawings. FIG. 1 is a perspective view of a wafer to be processed in a manufacturing method for a device chip according to a preferred embodiment of the present invention. FIG. 2 is a sectional view of the wafer depicted in FIG. 1. FIG. 3 is a flow chart of the manufacturing method for a device chip according to the embodiment of the present invention.

The manufacturing method for a device chip according to the embodiment of the present invention is a processing method of a wafer 1 illustrated in FIG. 1. As illustrated in FIG. 1 and FIG. 2, the wafer 1 to be processed in the manufacturing method for a device chip according to the embodiment of the present invention is such a wafer as a semiconductor wafer in a circular disc shape including a base substrate 2, a laser beam absorbing layer 3 layered on the base substrate 2, and a device layer 4 provided on an upper surface 31 of the laser beam absorbing layer 3.

In this embodiment, the base substrate 2 includes silicon and is formed in a circular disc shape. The laser beam absorbing layer 3 includes resin and is formed of polyimide in this embodiment. The laser beam absorbing layer 3 is layered on the base substrate 2 all over a front surface 21 of the base substrate 2.

As illustrated in FIG. 1, the device layer 4 has devices 6 formed in separate respective regions demarcated by a plurality of division lines 5 which cross each other. The devices 6 are circuits such as integrated circuits (IC) or large scale integration circuits (LSIs), power devices, or micro electro mechanical systems (MEMS), for example.

As illustrated in FIG. 2, the device layer 4 includes an insulating layer 7, a silicon layer 8, and a rewiring layer 9. The insulating layer 7 is formed on the upper surface 31 of the laser beam absorbing layer 3. The silicon layer 8 is formed on the insulating layer 7. The rewiring layer 9 is formed on the silicon layer 8. The insulating layer 7 is what is called a BOX layer made of SiO₂. The silicon layer 8 includes silicon. The rewiring layer 9 constitutes devices 6.

As described above, in this embodiment, the wafer 1 is what is generally called an SOI wafer which forms the device layer 4 on the upper surface 31 of the laser beam absorbing layer 3. In the embodiment, the wafer 1 has the base substrate 2 and the laser beam absorbing layer 3 removed and is divided into individual device chips along the division lines 5. In the embodiment, the device chips thus divided each include only the device layer 4 and have a thickness of substantially 10 μm.

The wafer 1 described above is manufactured, for example, by bonding to each other a silicon wafer having the laser beam absorbing layer 3 and the insulating layer 7 layered in this order on the base substrate 2 and a silicon wafer having the rewiring layer 9 layered on the silicon layer 8 as a base substrate. In addition, the wafer 1 is manufactured, for example, by bonding to each other a silicon wafer having the laser beam absorbing layer 3 layered on the base substrate 2 and a silicon wafer having the insulating layer 7 layered on one surface of the silicon layer 8 as a base substrate and the rewiring layer 9 layered on the other surface of the silicon layer 8.

In the manufacturing method for a device chip according to the embodiment of the present invention, the base substrate 2 and the laser beam absorbing layer 3 which are included in the wafer 1 are removed, and the wafer 1 is divided along the plurality of division lines 5, to thereby manufacture each device chip. As illustrated in FIG. 3, the manufacturing method for a device chip according to the embodiment of the present invention includes a wafer preparation step 1001, a device layer dividing step 1002, a transfer member arranging step 1003, a lift-off step 1004, and a device pick-up step 1005.

(Wafer Preparation Step)

The wafer preparation step 1001 is a step of preparing a wafer having the configuration described above. In the wafer preparation step 1001, the wafer 1 having the configuration described above is prepared.

(Device Layer Dividing Step)

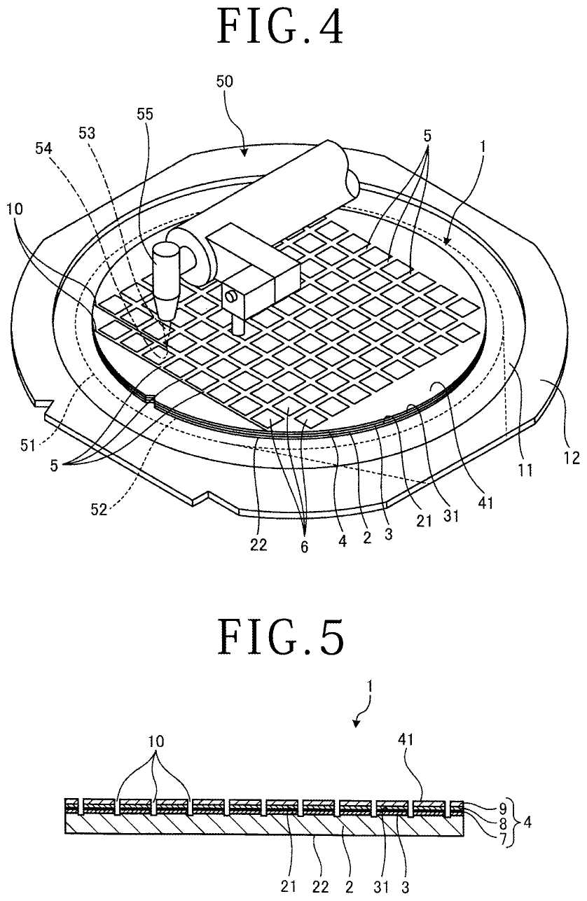

FIG. 4 is a perspective view schematically illustrating the device layer dividing step of the manufacturing method for a device chip depicted in FIG. 3. FIG. 5 is a schematic sectional view of the wafer that has undergone the device layer dividing step of the manufacturing method for a device chip depicted in FIG. 3. In this embodiment, the device layer dividing step 1002 is a step of forming division grooves 10 for dividing at least the device layer 4 into individual device chips along the respective division lines 5.

In this embodiment, the device layer dividing step 1002 is carried out in such a manner that, as illustrated in FIG. 4, a known mounter attaches a circular disc-shaped tape 11 larger in diameter than the wafer 1 to a back surface 22 of the base substrate 2 of the wafer 1 on the back side of a front surface 21 thereof and also attaches an annular frame 12 having an inner diameter larger than an outer diameter of the wafer 1 to an outer peripheral edge of the tape 11 to support the wafer 1 through the tape 11 inside an inner opening of the annular frame 12.

In this embodiment, the device layer dividing step 1002 is carried out in such a manner that a laser processing apparatus 50 causes the back surface 22 of the base substrate 2 of the wafer 1 to be held under suction through the tape 11 on a holding surface 52 of a chuck table 51. In the embodiment, the device layer dividing step 1002 is further carried out in such a manner that the laser processing apparatus 50 sets a focusing point 54 of a laser beam 53 to the device layer 4 and applies the laser beam 53 of an absorption wavelength with respect to the wafer 1 to each of the division lines 5 of the wafer 1 from a laser beam applying unit 55 while moving the chuck table 51 relative to the laser beam applying unit 55 along each of the division lines 5. The laser processing apparatus 50 thereby performs ablation processing on the wafer 1.

In this embodiment, the device layer dividing step 1002 is further carried out in such a manner that the laser processing apparatus 50 performs ablation processing on each of the division lines 5 of the wafer 1, to form division grooves 10 which divide the device layer 4 into individual devices 6. In this embodiment, as illustrated in FIG. 5, the device layer dividing step 1002 is then carried out in such a manner that the laser processing apparatus 50 forms division grooves 10 in all of the division lines 5 of the wafer 1. Note that, in this embodiment, the division grooves 10 divide the device layer 4 and the laser beam absorbing layer 3 into each device 6.

Note that, in this embodiment, the device layer dividing step 1002 is carried out in such a manner that the laser processing apparatus 50 performs ablation processing on the division lines 5 of the wafer 1 to form the division grooves 10. However, in the present invention, the device layer dividing step 1002 may be carried out in such a manner that a cutting apparatus causes a cutting blade to cut in the division lines 5 of the device layer 4 of the wafer 1 to form the division grooves 10. Alternatively, in the present invention, the device layer dividing step 1002 may be carried out in such a manner that the division lines 5 of the device layer 4 of the wafer 1 are subjected to etching such as wet etching or dry etching to form the division grooves 10.

(Transfer Member Arranging Step)

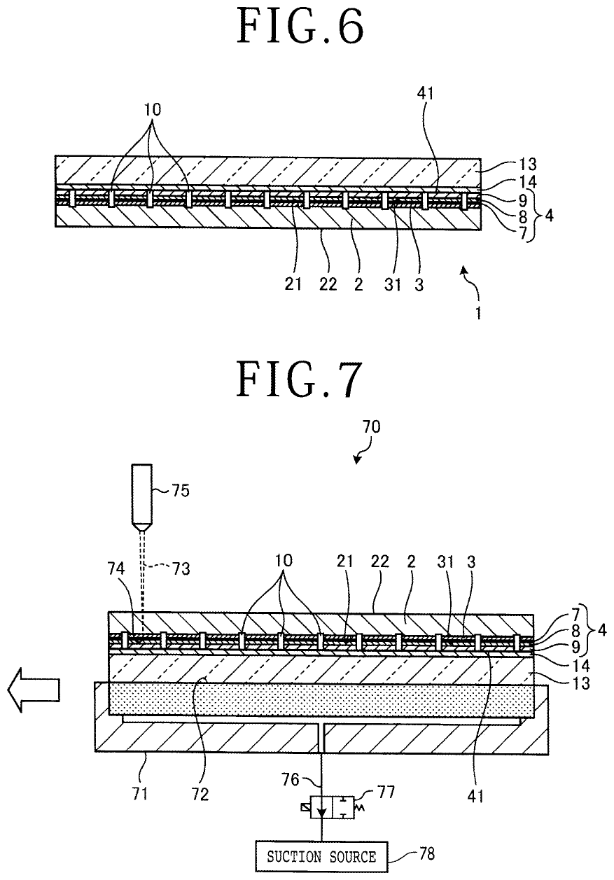

FIG. 6 is a schematic sectional view of the wafer that has undergone a transfer member arranging step of the manufacturing method for a device chip depicted in FIG. 3. In the transfer member arranging step 1003, a transfer member 13 is arranged on a front surface 41 of the device layer 4 before the lift-off step 1004 is carried out.

In this embodiment, the transfer member arranging step 1003 is carried out in such a manner that an adhesive 14 is applied to the front surface 41 of the device layer 4 of the wafer 1. Such an adhesive 14 reduces its adhesion force as a result of application of an external stimulus. As illustrated in FIG. 6, the transfer member 13 is attached to the adhesive 14 and arranged to the front surface 41 of the device layer 4 through the adhesive 14, while the tape 11 is removed from the back surface 32 of the wafer 1. Note that, in this embodiment, application of an external stimulus includes light irradiation of ultraviolet ray or heating, for example.

In this embodiment, the transfer member 13 is made of a hard material and formed in a circular disc shape having the same diameter as the wafer 1. In this embodiment, the transfer member 13 includes glass.

In addition, in this embodiment, as the transfer member 13, a liquid resin (ResiFlat (registered trademark) manufactured by DISCO Corporation) may be applied to the front surface 41 of the device layer 4 and be cured. As another alternative, in the present invention, the transfer member 13 may be a surface protective tape including a base sheet and an adhesive layer. As a further alternative, in the present invention, adoptable is the transfer member 13 obtained by attaching a circular disc-shaped plate including a hard material such as metal, ceramic, or silicon to the front surface 41 of the device layer 4 through the adhesive 14.

(Lift-Off Step)

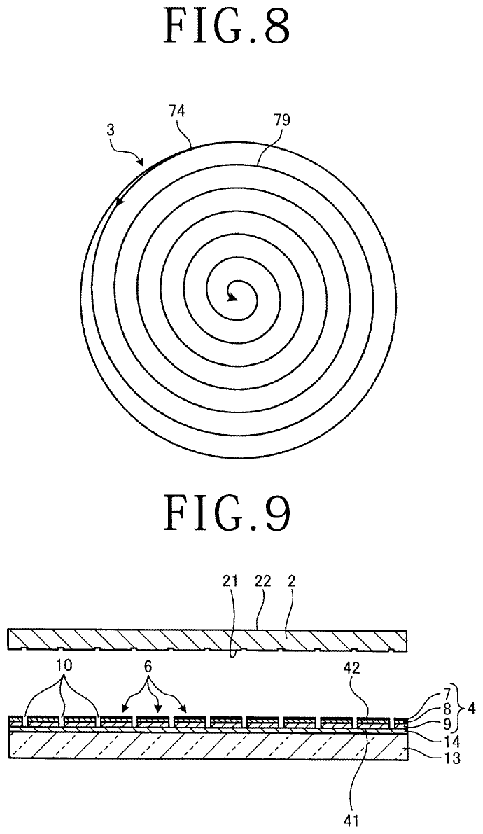

FIG. 7 is a sectional view schematically illustrating a state in which a laser beam is applied to the wafer in a lift-off step of the manufacturing method for a device chip depicted in FIG. 3. FIG. 8 is a plan view illustrating a trajectory of a focusing point of the laser beam in the lift-off step of the manufacturing method for a device chip depicted in FIG. 3. FIG. 9 is a sectional view schematically illustrating a state in which a base substrate is removed in the lift-off step of the manufacturing method for a device chip depicted in FIG. 3.

The lift-off step 1004 is a step of, after the device layer dividing step 1002 is carried out, applying a laser beam 73 of an absorption wavelength with respect to the laser beam absorbing layer 3 from the base substrate 2 side, and lifting off the devices 6 from the front surface 21 of the base substrate 2. In this embodiment, the lift-off step 1004 is carried out in such a manner that a laser processing apparatus 70 opens an opening/closing valve 77 provided in a suction passage 76 and sucks a holding surface 72 of a chuck table 71 through the suction passage 76 by a suction source 78 to hold under suction the front surface 41 side of the device layer 4 of the wafer 1 through the transfer member 13 onto the holding surface 72 of the chuck table 71.

In this embodiment, the lift-off step 1004 is further carried out in such a manner that the laser processing apparatus 70 sets a focusing point 74 of the laser beam 73 to the laser beam absorbing layer 3 of the wafer 1 held on the chuck table 71, and as illustrated in FIG. 7, causes a laser beam applying unit 75 to apply the pulsed laser beam 73 of a wavelength having transmissivity to the base substrate 2 and an absorption wavelength with respect to the laser beam absorbing layer 3, from the base substrate 2 side of the wafer 1 toward the laser beam absorbing layer 3.

In the lift-off step 1004, as illustrated in FIG. 8, the laser processing apparatus 70 first positions the focusing point 74 of the laser beam 73 to the outermost peripheral edge of the laser beam absorbing layer 3, and then applies the pulsed laser beam 73 to the wafer 1, while moving the focusing point 74 of the laser beam 73 and the chuck table 71 relative to each other in such a manner that the focusing point 74 moves onto a trajectory 79 in a spiral shape gradually heading toward the center of the laser beam absorbing layer 3 while moving from the outermost peripheral edge of the laser beam absorbing layer 3 in a circumferential direction thereof.

The pulsed laser beam 73 has a wavelength having transmissivity to the base substrate 2 and an absorption wavelength to the laser beam absorbing layer 3. Accordingly, in the lift-off step 1004, the laser beam absorbing layer 3 to which the pulsed laser beam 73 has been applied is broken, and gas is generated. In this embodiment, the lift-off step 1004 is carried out in such a manner that, as illustrated in FIG. 9, the base substrate 2 is peeled off from a back surface 42 on the back side of the front surface 41 of the device layer 4 of the wafer 1, that is, from the insulating layer 7, to thereby be removed from the device layer 4, that is, from each device 6. It is to be noted that, in this embodiment, the wavelength of the pulsed laser beam 73 is 1064 nm.

(Device Pick-Up Step)

The device pick-up step 1005 is a step of, after the lift-off step 1004 is carried out, picking up the devices 6 having been cut into individual pieces, from the transfer member 13.

In this embodiment, the device pick-up step 1005 is carried out in such a manner that an external stimulus is applied to the adhesive 14, thereby lowering an adhesive force of the adhesive 14. In this embodiment, the device pick-up step 1005 is further carried out in such a manner that, after the adhesive force of the adhesive 14 is lowered, an unillustrated picker holds under suction the devices 6, for example, and each device 6 is picked up from the transfer member 13, one by one.

It is to be noted that, in the present invention, device pick-up step 1005 may be carried out in such a manner that a tape or the like is attached to the back surface 42 side of the device layer 4, the devices 6 are caused to be transferred to the tape, and then, each device 6 is picked up. Alternatively, in the present invention, the device pick-up step 1005 may be carried out in such a manner that the transfer member 13 is divided for each device 6, and each device 6 is picked up along with each transfer member 13 which has been divided into individual pieces.

The manufacturing method for a device chip according to the embodiment described above is carried out as follows. In the wafer preparation step 1001, prepared is the wafer 1 including the base substrate 2, the laser beam absorbing layer 3 layered on the base substrate 2, and the device layer 4 being layered on the upper surface 31 of the laser beam absorbing layer 3 and having the devices 6 formed in the respective separate regions demarcated by the plurality of crossing division lines 5. Then, after the device layer 4 is divided in the device layer dividing step 1002, the laser beam 73 of an absorption wavelength with respect to the laser beam absorbing layer 3 is applied from the base substrate 2 side in the lift-off step 1004, so that the laser beam 73 is absorbed into the laser beam absorbing layer 3, thereby removing the base substrate 2 from the back surface 42 of the device layer 4. After the lift-off step 1004 is carried out, the wafer 1 is divided into individual device chips having only the device layer 4. As a result, the manufacturing method for a device chip according to the embodiment of the present invention provides an effect of achieving a novel process of manufacturing a device chip having only the device layer 4.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A manufacturing method for a device chip, comprising:
a wafer preparation step of preparing a wafer including a base substrate, a laser beam absorbing layer layered on a front surface of the base substrate, and a device layer being layered on the laser beam absorbing layer and having devices formed in respective separate regions demarcated by a plurality of crossing division lines;
a device layer dividing step of forming respective division grooves that divide at least the device layer into individual device chips along the plurality of division lines; and
a lift-off step of, after the device layer dividing step is carried out, applying a laser beam of such a wavelength as to be absorbed in the laser beam absorbing layer, from the base substrate side, and lifting off a device chip from the front surface of the base substrate.

2. The manufacturing method for a device chip according to claim 1, further comprising:
a transfer member arranging step of arranging a transfer member to a front surface of the device layer, before the lift-off step is carried out.
